(19) United States
(12) Patent Application Publication
(10) Pub. No.: US 2004/0266204 A1
(43) Pub. Date: Dec. 30, 2004

(54) Method for patterning metal wire in semiconductor device

(76) Inventors: Kwan-Yong Lim, Ichon-shi (KR); Heung-Jae Cho, Ichon-shi (KR); Jung-Ho Lee, Ichon-shi (KR); Se-Aug Jang, Ichon-shi (KR); Yong-Soo Kim, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/732,528

(22) Filed: Dec. 11, 2003

(30) Foreign Application Priority Data
Jun. 30, 2003 (KR) 2003-43105

(51) Int. Cl. H01L 21/302; H01L 21/461

(52) U.S. Cl. 438/706

(57) ABSTRACT

The present invention relates to a method for patterning a metal wire of a semiconductor device capable of preventing an incidence of abnormal oxidation of a metal layer during a patterning of a gate electrode, a bit line or a metal lining as simultaneously as being capable of proceeding a lithography process easily. The method includes the steps of: forming stack layers having at least a metal layer as an upper most layer on a substrate; forming an anti-reflective coating layer on the stack layers by employing an atomic layer deposition technique; forming a photoresist pattern on the anti-reflective coating layer; patterning the anti-reflective coating layer by using the photoresist pattern as an etch mask; and forming a metal wire by etching the stack layers with use of the patterned anti-reflective coating layer as an etch mask.

### FIELD OF THE INVENTION

The present invention relates to a method for fabricating a semiconductor device; and, more particularly, to a method for patterning a metal wire of a semiconductor device by using an anti-reflective coating (ARC) layer.

### DESCRIPTION OF RELATED ARTS

Generally, a photoresist is used in a lithography process performed as one of processes for fabricating a semiconductor device. However, for a lithography process for patterning a gate electrode, a bit line or a metal line related to the use of a metal wire with a line-width of below about 100 nm, a wavelength of a light source is longer or nearly equal to a line-width of a subject to be patterned. Thus, in an actual patterning, the light source incident to a photoresist interferes with a reflected light after the incident light source hits a bottom material. This interference results in a difficulty in a fine patterning.

The use of an anti-reflective coating (ARC) layer is adopted to solve the above mentioned problem. For instance, the ARC layer is deposited on an upper surface of a bottom material to be patterned, and a photoresist is coated thereon. Afterwards, a lithography process is performed to obtain a fine patterning. This ARC layer is also called the bottom anti-reflective coating (BARC) layer. Particularly, organic materials or inorganic materials such as SiO₂ or SiON (hereinafter referred to as SiOₓN_{y}) are typically used for the ARC layer.

FIGS. 1A to 1D are cross-sectional-views illustrating a method for patterning a conventional metal wire, particularly a gate electrode of a semiconductor device. Referring to FIG. 1A, a gate insulation layer 12 is deposited on a substrate 11, and a polysilicon layer 13, a diffusion barrier layer 14 and a tungsten layer 15 are sequentially deposited on the gate insulation layer 12.

Then, a hard mask nitride layer 16 is deposited on the tungsten layer 15. A hard mask tungsten layer 17 is formed on the hard mask nitride layer 16.

After the deposition of the hard mask tungsten layer 17, a silicon oxynitride (SiOₓN_{y}) layer 18 is deposited as an ARC layer on the hard mask tungsten layer 17 by performing a chemical vapor deposition (CVD) technique. Hereinafter, such silicon oxynitride layer 18 is called as the CVD-SiOₓN_{y} ARC layer 18. A photoresist 19 is then coated on the CVD-SiOₓN_{y} ARC layer 18.

Next, the photoresist 19 is patterned through a photo-exposure and developing process. Thereafter, the CVD-SiOₓN_{y} ARC layer 18, the hard mask tungsten layer 17 and the hard mask nitride layer 16 are sequentially patterned by using the patterned photoresist 19 as an etch mask.

Referring to FIG. 1B, the photoresist 19 and the CVD-SiOₓN_{y} ARC layer 18 are removed. At this time, an oxygen plasma is used for the removal of the photoresist 19 and the CVD-SiOₓN_{y} ARC layer 18.

Referring to FIG. 1C, the tungsten layer 15 and the diffusion barrier layer 14 are etched with use of a dual hard mask including the patterned hard mask tungsten layer 17 and the hard mask nitride layer 16 as an etch mask. At this time, the hard mask tungsten layer 17 is mostly used away because of an over-etching continued to completely etch the diffusion barrier layer 14. Therefore, a portion of the hard mask nitride layer 16 is also used away, resulting in an etching of a partial surface of the polysilicon layer 13.

Referring to FIG. 1D, the polysilicon layer 13 is etched by using the hard mask nitride layer 16 as an etch mask to thereby completing a gate electrode patterning process.

FIG. 2 is a micrograph of a structure obtained after depositing the SiO₂ layer on an exposed portion of the tungsten layer at a temperature of about 400° C. with use of a plasma enhanced tetra-ethyl-ortho-silicate (PE-TEOS) technique, which is one type of the CVD technique. It is observed that a thin and rough tungsten oxide (WOₓ) layer is formed.

As shown, since the SiOₓN_{y} layer is deposited as the ARC layer under a high-temperature oxidative ambient by using the CVD technique, such metal layer as a tungsten layer is not applicable with this type of deposition. That is, in case that the SiOₓN_{y} layer is deposited on an upper surface of the tungsten layer, abnormal oxidation takes place at the tungsten layer because of the high temperature oxidative ambient of above about 400° C. Typically, it is known that the abnormal oxidation occurs when the tungsten layer reacts with oxygen at a temperature of above about 350° C. This abnormal oxidation reduces amounts of tungsten within the tungsten layer, resulting in an increase of a resistance of a metal wire. Also, it is difficult to obtain a uniform patterning because a rough tungsten oxide layer is formed on the tungsten layer as a result of the abnormal oxidation.

### SUMMARY OF THE INVENTION

It is, therefore, an object of the present invention to provide a method for patterning a metal wire of a semiconductor device capable of preventing an abnormal oxidation of the metal wire and performing easily a lithography process with use of an anti-reflective coating (ARC) layer.

In accordance with an aspect of the present invention, there is provided a method for patterning a metal wire of a semiconductor device, including the steps of: forming stack layers having at least a metal layer as an upper most layer on a substrate; forming an anti-reflective coating layer on the stack layers by employing an atomic layer deposition technique; forming a photoresist pattern on the anti-reflective coating layer; patterning the anti-reflective coating layer by using the photoresist pattern as an etch mask; and forming a metal wire by etching the stack layers with use of the patterned anti-reflective coating layer as an etch mask.

In accordance with another aspect of the present invention, there is also provided a method for patterning a gate electrode of a semiconductor device, including the steps of: forming a gate insulation layer on a substrate; forming a gate structure including at least a metal layer on the gate insulation layer; forming a hard mask including at least a metal layer on the gate structure; forming an anti-reflective coating layer on the hard mask by employing an atomic layer deposition technique; forming a photoresist pattern on the anti-reflective coating layer; patterning the anti-reflective coating layer and the hard mask by using the photoresist pattern as an etch mask; and forming a gate electrode by etching the gate structure with use of the patterned anti-reflective coating layer and the hard mask as an etch mask.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1D are cross-sectional views illustrating a conventional method for patterning a metal wire of a semiconductor device;

FIG. 2 is a micrograph of a structure obtained after depositing a silicon oxide (SiO₂) layer on an exposed portion of a conventional tungsten layer at a temperature of about 400° C. with use of a plasma enhanced tetra-ethyl-ortho-silicate (PE-TEOS) technique;

FIG. 3 is a flowchart showing steps of a method for patterning a metal wire of a semiconductor device in accordance with a preferred embodiment of the present invention;

FIGS. 4A to 4D are cross-sectional views illustrating a method for patterning a gate electrode by applying the method shown in FIG. 3; and

FIG. 5 is a micrograph of a structure obtained after depositing a SiO₂ layer on an exposed portion of a tungsten layer at a temperature of about 100° C. with use of an atomic layer deposition (ALD) technique in accordance with the preferred embodiment of the present invention.

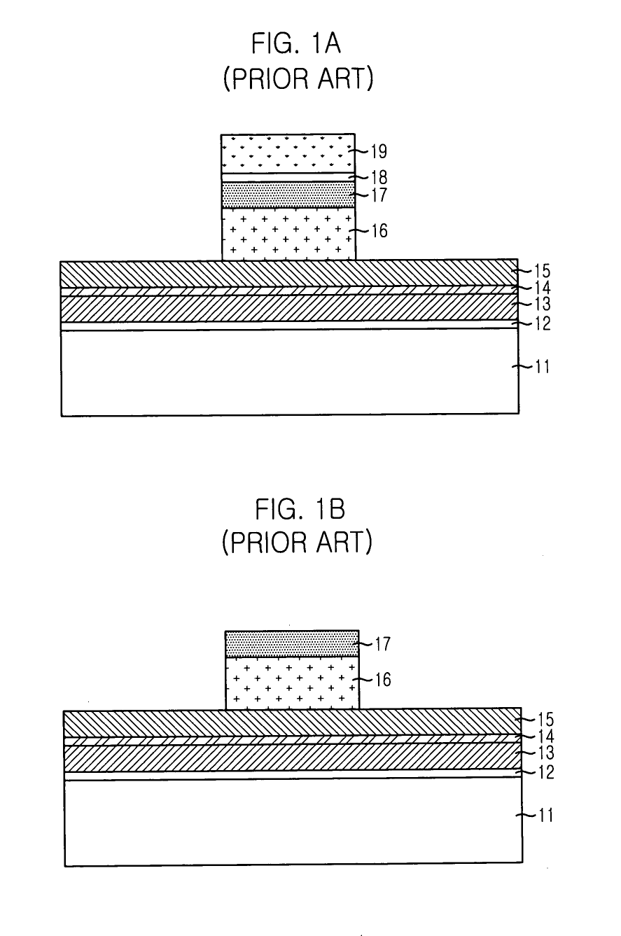

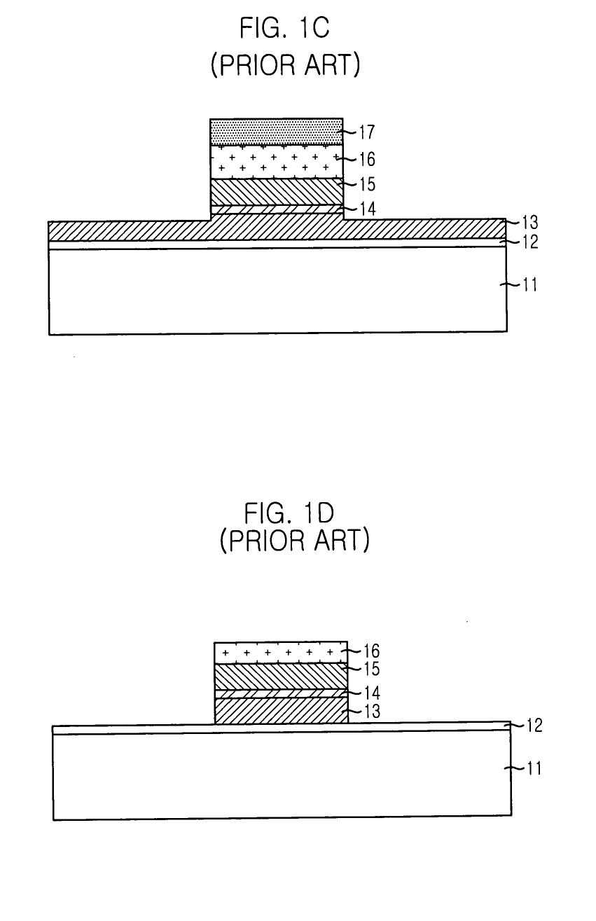

### DETAILED DESCRIPTION OF THE INVENTION

Hereinafter, a preferred embodiment of a method for patterning a metal wire of a semiconductor device will be described in detail with reference to the accompanying drawings.

Particularly, according to the preferred embodiment of the present invention, an accurate and uniform patterning is possible by depositing a thin anti-reflective coating (ARC) layer on a metal wire by using an atomic layer deposition (ALD) technique capable of a low temperature deposition and then performing a photo-mask process for patterning the metal wire.

That is, in contrast to the conventional use of a chemical vapor deposition (CVD) technique for depositing the ARC layer in a high temperature oxidative ambient, the ALD technique used in the deposition of the ARC layer prevents an abnormal oxidation of the metal wire because of an enabled low temperature deposition.

Typically, the ALD technique includes a series of steps proceeding first by supplying a source gas to make the source gas chemically adsorbed to a surface of a substrate and then purging the physically adsorbed remaining source gas. Afterwards, a reaction gas is supplied to a layer of chemically adsorbed source gas and reacts with the source gas so that an intended atomic layer is deposited. The remaining reaction gas is purged thereafter.

The ALD technique uses a surface reaction mechanism, which provides a more stable and uniform thin layer. Also, the ALD technique suppresses more effectively particle generation occurring due to a gas phase reaction than a CVD technique since the ALD technique supplies separately the source gas and the reaction gas in a specific order and purges sequentially these gases.

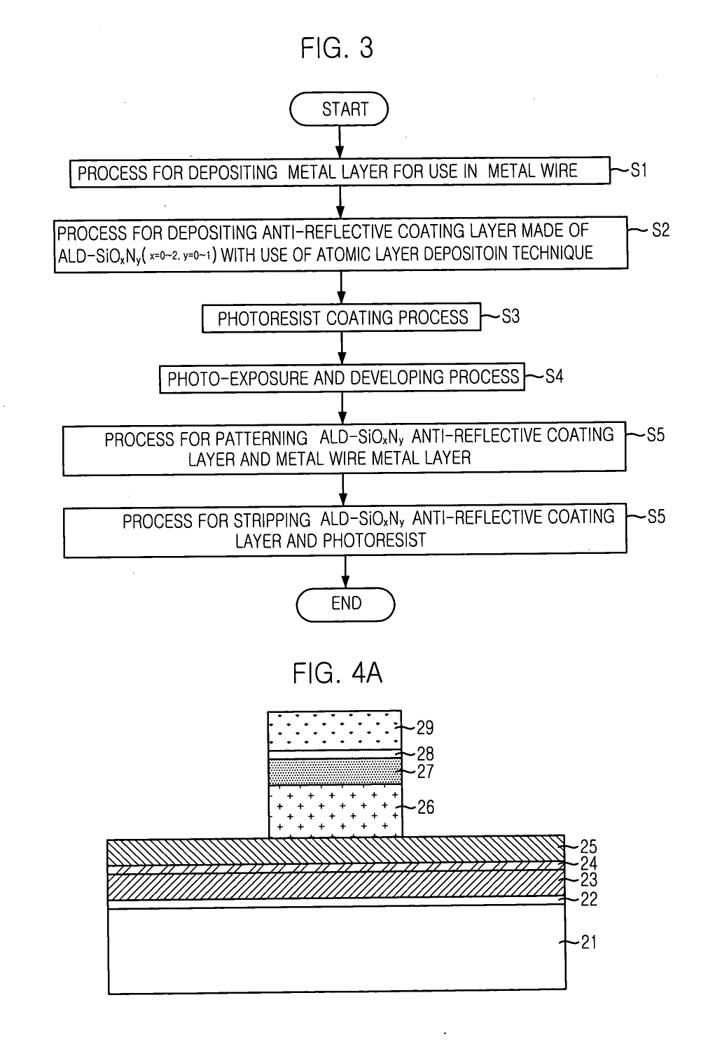

FIG. 3 is a flowchart showing steps of a method for patterning a metal wire of a semiconductor device in accordance with the preferred embodiment of the present invention.

As shown, the method for patterning the metal wire includes a series of processes; they are, a process S1 for depositing a metal layer for use in a metal wire (hereinafter referred to as the metal wire metal layer), a process S2 for depositing an ALD-silicon oxynitride (SiOₓN_{y}) ARC layer, a process S3 for coating a photoresist, a photo-exposure and developing process S4, a process S5 for patterning the ALD-SiOₓN_{y} ARC layer and the metal wire metal layer and a process S6 for striping away the ALD-SiOₓN_{y} ARC layer and the photoresist. Herein, the subscript x representing the number of oxygen atoms ranges from about 0 to about 2, while the subscript y representing the number of nitrogen atoms ranges from about 0 to about 1.

Also, in the process S2 for depositing the ALD-SiOₓN_{y} ARC layer, the SiOₓN_{y} ARC layer is deposited after the deposition of the metal wire metal layer by employing the ALD technique. Especially, ALD-SiOₓN_{y} ARC layer is deposited at a temperature ranging from about 70° C. to about 350° C. in order to prevent an abnormal oxidation of the metal wire metal layer. At this time, the deposition temperature of about 70° C. to about 350° C. is lower than a typical deposition temperature of about 400° C. required for the conventional CVD technique.

Eventually, the ALD technique deposits the SiOₓN_{y} ARC layer at this lowered deposition temperature of about 70° C. to about 350° C. being capable of securing required properties of the SiOₓN_{y} ARC layer and thus simultaneously preventing the abnormal oxidation of the metal wire metal layer.

For the ALD-SiOₓN_{y} ARC layer deposition, a source gas of silicon is selected from a group consisting of SiCl₆, SiCl₄, SiCl₂H₂, SiH₄, SiF₄ and SiF₆, while a source gas of oxygen is selected from a group consisting of O₂, O₃, H₂O, D₂O, NO and N₂O. Herein, the D represents deuterium. Also, a source gas of nitrogen is selected from a group consisting of N₂, NH₃, NO, N₂O and NF₃. Each source gas is supplied after being activated by using a radio frequency (RF) plasma or a microwave plasma. Although the final thickness of the ALD-SiOₓN_{y} ARC layer is different from each other depending on the thickness of a bottom layer, a preferable thickness of the ALD-SiOₓN_{y} ARC layer ranges from about 10 Å to about 2000 Å.

Meanwhile, the ALD-SiOₓN_{y} ARC layer is less dense because it is deposited at a low temperature. Also, the use of the silicon source gas containing Cl or F causes impurities existing in the ALD-SiOₓN_{y} ARC layer, e.g., Cl or F, to remain within the ALD-SiOₓN_{y} ARC layer. The remaining impurities may result in a degradation of properties of the ALD-SiOₓN_{y} ARC layer. Therefore, an annealing process is performed at a temperature ranging from about 400° C. to about 1000° C. in an atmosphere of N₂ gas, H₂ gas or a mixed gas of N₂ and H₂ for about 10 seconds to about 30 minutes in order to increase the density of the ALD-SiOₓN_{y} ARC layer and remove the remaining impurities. At this time, even though the annealing process proceeds at a high temperature, a thermal budget exerted to the metal wire metal layer is suppressed since the ALD-SiOₓN_{y} ARC layer is already formed. Also, the metal wire metal layer is not subjected to the abnormal oxidation because the ALD-SiOₓN_{y} ARC layer is performed in an atmosphere of the N₂ gas, H₂ gas or mixed gas of N₂ and H₂.

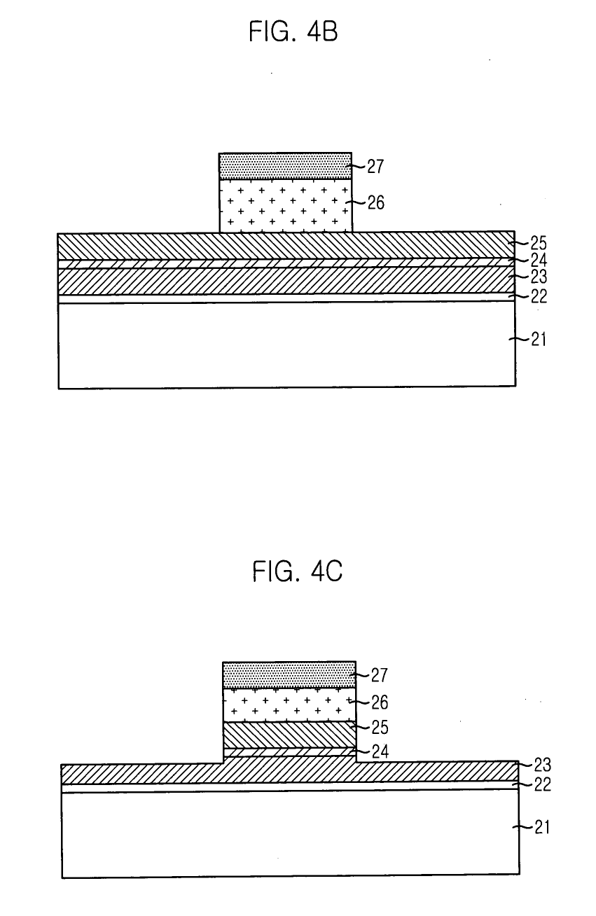

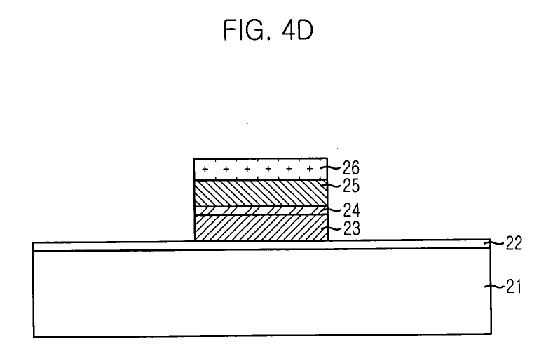

FIGS. 4A to 4D are cross-sectional views illustrating a method for patterning a gate electrode by applying the method shown in FIG. 3.

Referring to FIG. 4A, a gate insulation layer 22 is deposited on a substrate 21, and then, a polysilicon layer 23, a diffusion barrier layer 24 and a tungsten layer 25 are sequentially deposited thereon. Afterwards, a hard mask nitride layer 26 is deposited on the tungsten layer 25, and a hard mask tungsten layer 27 is then formed on the hard mask nitride layer 26. At this time, the gate insulation layer 22 is a SiO₂ layer obtained after thermally oxidating the substrate 21. Also, it is possible to use a polysilicon-germanium layer (polySi₁₋ₓGeₓ), where x ranges from about 0.01 to about 0.99, in addition to the use of the polysilicon layer 23. Also, the diffusion barrier layer 24 such as a barrier layer for preventing reciprocal diffusions between the polysilicon layer 23 and the tungsten layer 25. The diffusion barrier layer 24 is formed by using a tungsten nitride layer WNₓ, where x ranges from about 0.1 to about 2.0 or a silicon nitride layer SiNₓ, where x ranges from about 0.1 to about 2.0. Herein, the WNₓ has a thickness ranging from about 10 Å to about 300 Å, while the SiNₓ has a thickness ranging from about 5 Å to about 20 Å. Also, any one of a TiAlₓN_{y} layer, a HfNₓ layer, a ZrNₓ layer, a TaNₓ layer, a TaSiₓN_{y} layer, a TiNₓ layer and an AlNₓ layer can be still used for forming the diffusion barrier layer 24. Herein, subscripts x and y each representing atomic ratios range from about 0.1 to about 4.0, respectively. The hard mask nitride layer 26 is a silicon nitride layer made of Si₃N₄. In addition to the use of tungsten for the tungsten layer 25 and the hard mask tungsten layer 27, such material as Mo, Ta, Ti, Ru, Ir and Pt can be also used.

Next, the ALD-SiOₓN_{y} ARC layer 28 is deposited on the hard mask tungsten layer 27 with a thickness in a range from about 10 Å to about 2000 Å. At this time, subscript x representing the number of oxygen atoms ranges from about 0 to 2, while subscript y representing the number of nitrogen atoms ranges from about 0 to about 1. Particularly, the ALD-SiOₓN_{y} ARC layer 28 is deposited by performing the processes explained in FIG. 3. As described above, since the ALD technique deposits the SiOₓN_{y} ARC layer 28 at a temperature of about 70° C. to about 350° C. lower than the deposition temperature of about 400° C. required for the typical CVD technique, the SiOₓN_{y} ARC layer is directly deposited on the hard mask tungsten layer 27 without an incidence of the abnormal oxidation of the hard mask tungsten layer 27.

Subsequently, the aforementioned annealing process is performed at a temperature of about 400° C. to about 1000° C. in an atmosphere of N₂ gas, H₂ gas or a mixed gas of N₂ and H₂ for about 10 seconds to about 30 minutes in order to solve the problems of a lowered density of the ALD-SiOₓN_{y} ARC layer 28 due to a lower deposition temperature and a degradation of properties of the ALD-SiOₓN_{y} ARC layer 28 caused by the remaining impurities such as Cl or F after the use of the silicon source gas containing Cl or F. Afterwards, a photoresist 29 is coated on the ALD-SiOₓN_{y} ARC layer 28 and is patterned through the use of a photo-exposure and developing process. The ALD-SiOₓN_{y} ARC layer 28, the hard mask tungsten layer 27 and the hard mask nitride layer 26 are sequentially patterned by using the patterned photoresist 29 as an etch mask.

Referring to FIG. 4B, the photoresist 29 and the ALD-SiOₓN_{y} ARC layer 28 are striped away by using an oxygen plasma.

Referring to FIG. 4C, the tungsten layer 25 and the diffusion barrier layer 24 are etched by using a double hard mask including the patterned hard mask tungsten layer 27 and the hard mask nitride layer 26 as an etch mask. At this time, an over-etching occurs to completely etch the above layers down to the diffusion barrier layer 24. However, the hard mask tungsten layer 27 used as the etch mask is mostly etched away because of this over-etching, and thus, the hard mask nitride layer 26 is also partially etched away. As a result, a partial portion of the polysilicon layer 23 is started to be etched.

Referring to FIG. 4D, the polysilicon layer 23 is then further etched by using the hard mask nitride layer 26 as an etch mask, thereby completing the process for patterning the gate electrode.

In this preferred embodiment, a patterning of a polymetal gate structure constructed by sequentially stacking the polysilicon layer 23, the diffusion barrier layer 24 and the tungsten layer 25 is exemplified. However, the present invention can be applied to a patterning of a polycide gate structure including sequentially stacked a polysilicon layer and a silicide layer or of a metal gate structure including only metal layer(s). For instance, the silicide layer is made of a material selected from a group consisting of tungsten silicide WSiₓ, where x ranges from about 1 to about 3, cobalt silicide CoSiₓ, where x ranges from about 1 to about 3 and nickel silicide NiSiₓ, where x ranges from about 1 to about 3. Also, the metal layer(s) for constructing the metal gate structure is made of a material selected from a group consisting of TaN, TaSiN, TiN, TiAlN and HfN.

In addition, although the use of SiOₓN_{y} as the ARC layer is described in the above preferred embodiment, other types of the ARC layer can be used by selecting any one material from a group consisting of HfO₂, ZrO₂, Ta₂O₅, Al₂O₃, La₂O₃, Y₂O₃, CeO₂ and SiOₓF_{y}, where x and y range from about 0 to about 2 and from about 0 to about 1, respectively. That is, even if any one material selected from a group consisting of HfO₂, ZrO₂, Ta₂O₅, Al₂O₃, La₂O₃, Y₂O₃, CeO₂ and SiOₓF_{y} is deposited as the ARC layer for patterning the metal wire by using an ALD technique, the deposition temperature is still in a range from about 70° C. to about 350° C. Thus, it is possible to prevent an abnormal oxidation of the metal wire and obtain the metal wire more stable and uniform. Herein, for the SiOₓF_{y} layer formation, a source gas of silicon is selected from a group consisting of SiCl₆, SiCl₄, SiC₁₂H₂, SiH₄ and SiF₆. A source gas of oxygen is selected from a group consisting of O₂, O₃, H₂O, D₂O, NO and N₂O. Also, a source gas of fluorine is selected from a group consisting of F₂, NF₃, CF₄, CH₃F and CHF₃. For the formation of such a layer made of HfO₂, ZrO₂, Ta₂O₅, Al₂O₃, La₂O₃, Y₂O₃ or CeO₃, a source gas of metal is selected from a group consisting of Hf, Zr, Ta, Al, La, Y and Ce. A source gas of oxygen is selected from a group consisting of O₂, O₃, H₂O, D₂O, No and N₂₀.

Furthermore, the present invention can be also applicable to a patterning of a metal lining or a bit line using a metal layer such as a tungsten layer in addition to the patterning of the gate electrode.

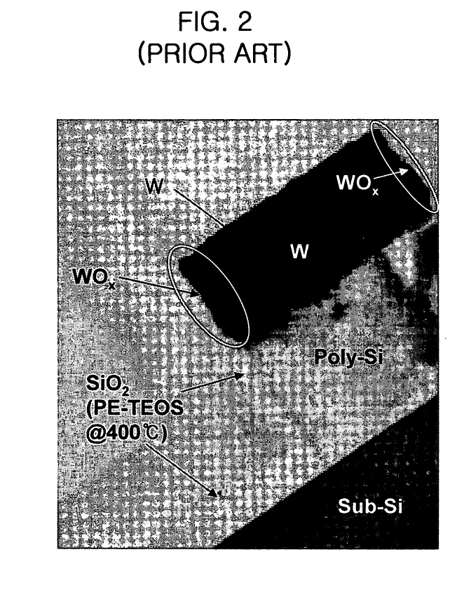

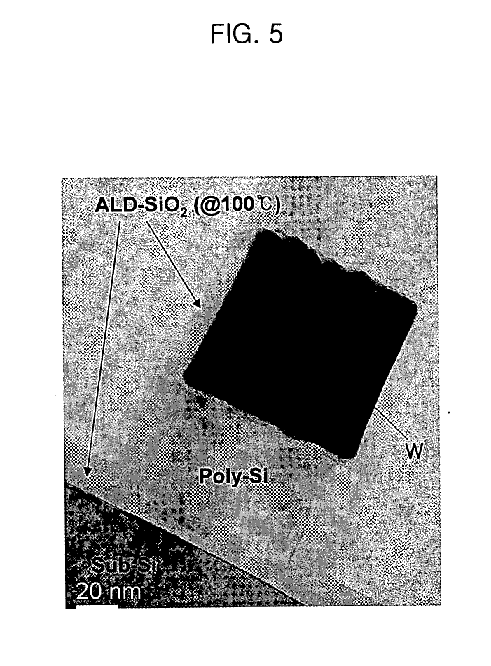

FIG. 5 is a micrograph of a structure obtained after depositing a SiO₂ layer on an exposed portion of a tungsten layer at a temperature of about 100° C. with use of an atomic layer deposition (ALD) technique in accordance with the preferred embodiment of the present invention. Unlike the rough surface of the WOₓ layer as shown in FIG. 2, an interfacial surface between the ALD-SiOₓN_{y} ARC layer and the tungsten layer is uniform.

Based on the above described preferred embodiment, the use of ALD technique makes it possible to deposit the ARC layer at a temperature lower than a temperature required for the conventional CVD technique. Thus, the ARC layer can be directly deposited on a surface of the metal wire metal layer without an abnormal oxidation, and thereby realizing an accurate and uniform fine patterning process.

While the present invention has been described with respect to certain preferred embodiments, it will be apparent to those skilled in the art that various changes and modifications may be made without departing from the scope of the invention as defined in the following claims.

What is claimed is:

1. A method for patterning a metal wire of a semiconductor device, comprising the steps of:
forming stack layers having at least a metal layer as an upper most layer on a substrate;
forming an anti-reflective coating layer on the stack layers by employing an atomic layer deposition technique;
forming a photoresist pattern on the anti-reflective coating layer;
patterning the anti-reflective coating layer by using the photoresist pattern as an etch mask; and
forming a metal wire by etching the stack layers with use of the patterned anti-reflective coating layer as an etch mask.

2. The method as recited in claim 1, wherein the step of forming the anti-reflective coating layer includes the step of performing an annealing process for densifying the anti-reflective coating layer and removing impurities within the anti-reflective coating layer.

3. The method as recited in claim 2, wherein the step of performing the annealing process proceeds at a temperature ranging from about 400° C. to about 1000° C. in an atmosphere of N₂ gas, H₂ gas or a mixed gas of N₂ and H₂ for about 10 seconds to about 30 minutes.

4. The method as recited in claim 1, wherein the step of forming the anti-reflective coating layer proceeds at a temperature ranging from about 70° C. to about 350° C.

5. The method as recited in claim 1, wherein the anti-reflective coating layer is made of one material selected from a group consisting of HfO₂, ZrO₂, Ta₂O₅, Al₂O₃, La₂O₃, Y₂O₃, CeO₂, SiOₓN_{y}, where x and y range from about 0 to about 2 and from about 0 to about 1, respectively and SiOₓF_{y}, where x and y range from about 0 to about 2 and from about 0 to about 1, respectively.

6. A method for patterning a gate electrode of a semiconductor device, comprising the steps of:
forming a gate insulation layer on a substrate;
forming a gate structure including at least a metal layer on the gate insulation layer;
forming a hard mask including at least a metal layer on the gate structure;
forming an anti-reflective coating layer on the hard mask by employing an atomic layer deposition technique;
forming a photoresist pattern on the anti-reflective coating layer;
patterning the anti-reflective coating layer and the hard mask by using the photoresist pattern as an etch mask; and
forming a gate electrode by etching the gate structure with use of the patterned anti-reflective coating layer and the hard mask as an etch mask.

7. The method as recited in claim 6, wherein the step of forming the anti-reflective coating layer includes the step of performing an annealing process for densifying the anti-reflective coating layer and removing impurities within the anti-reflective coating layer.

8. The method as recited in claim 7, wherein the step of performing the annealing process proceeds at a temperature ranging from about 400° C. to about 1000° C. in an atmosphere of N₂ gas, H₂ gas or a mixed gas of N₂ and H₂ for about 10 seconds to about 30 minutes.

9. The method as recited in claim 6, wherein the step of forming the anti-reflective coating layer proceeds at a temperature ranging from about 70° C. to about 350° C.

10. The method as recited in claim 6, wherein the anti-reflective coating layer is made of one material selected from a group consisting of HfO₂, ZrO₂, Ta₂O₅, Al₂O₃, La₂O₃, Y₂O₃, CeO₂, SiOₓN_{y}, where x and y range from about 0 to about 2 and from about 0 to about 1, respectively and SiOₓF_{y}, where x and y range from about 0 to about 2 and from about 0 to about 1, respectively.

11. The method as recited in claim 6, wherein the hard mask is formed by stacking a hard mask nitride layer and a hard mask metal layer, and the hard mask metal layer is made of one material selected from a group consisting of W, Mo, Ti, Ru, Ir and Pt.

12. The method as recited in claim 6, wherein the gate structure is one structure selected from a stack structure including a polysilicon layer or a polysilicon-germanium layer, a diffusion barrier layer and a metal layer, a stack structure including a polysilicon layer or a polysilicon-germanium layer and a silicide layer and a metal structure including metal layers.
